(19) United States
(12) Patent Application Publication
(10) Pub. No.: US 2004/0245643 A1
(43) Pub. Date: Dec. 9, 2004

(54) Semiconductor device and method of manufacturing the same

(75) Inventors: Toshiyuki Takewaki, Kanagawa (JP); Noriaki Oda, Kanagawa (JP); Ichiro Honma, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 10/859,319

(22) Filed: Jun. 3, 2004

(30) Foreign Application Priority Data
Jun. 3, 2003 (JP) 2003-158487

(51) Int. Cl. H01L 23/34; H01L 23/48

(52) U.S. Cl. 257/758

(57) ABSTRACT

A semiconductor device includes a first wiring layer section formed above a semiconductor substrate; and a second wiring layer section formed on the first wiring layer section. The latter includes a first interlayer insulating film; a plurality of first via-plugs formed in the first interlayer insulating film separated from each other by a first distance; and a plurality of first wiring lines formed on the plurality of first via-plugs in the first interlayer insulating film and connected with the plurality of first via-plugs. The second wiring layer section includes a second interlayer insulating film; a plurality of second via-plugs formed in the second interlayer insulating film, separated from each other by a second distance which is longer than the first distance; and a plurality of second wiring lines formed on the plurality of second via-plugs in the second interlayer insulating film and connected with the plurality of second via-plugs, respectively.

### BACKGROUND OF THE INVENTION

1. Field of the Invention

The present invention relates to a semiconductor device and a method of manufacturing the same, and more particularly to a semiconductor device which has a wiring structure using a damascene structure of metal containing copper and a method of manufacturing the same.

2. Description of the Related Art

As a wiring structure of a semiconductor device, a structure is known in which a local wiring layer section and a power supply wiring layer section are laminated in order on a semiconductor substrate on which a plurality of devices are formed. In such semiconductor device, copper (Cu) is used as material for a wiring line in the wiring layers and tungsten (W) is used as material for a via-plug to connect the wiring lines.

However, because the film forming temperature of tungsten is very high, copper in the wiring line aggregates so that a possibility that the wiring line is broken becomes high. On the other hand, there is an advantage that the via-plug using copper has a low contact resistance and a high endurance to thermal stress, compared with the via-plug using tungsten. From the above reasons, copper is generally used for the via-plug, in recent years.

As a method of forming a wiring line and via-plug of copper, the dual damascene method and the single damascene method are known. The dual damascene method has an advantage in the point that a CMP process is less by one time than the single damascene method, and a wiring line resistance is small because a barrier metal film is not put between the wiring line and the via-plug. Therefore, at present, all of the wiring lines and the via-plugs are often formed by the dual damascene method.

Referring to FIG. 1, the structure of a semiconductor device will be described. FIG. 1 is a cross sectional view showing the wiring structure of the semiconductor device. The semiconductor device 101 is formed onto a semiconductor substrate 140 and is composed of a device section 131, a local wiring layer section 133 and a power supply wiring layer section 132. The device section 131 is composed of the semiconductor substrate 140, a plurality of devices and wiring lines (not shown). The local wiring layer section 133 is formed onto the device section 131 and is composed of a wiring layer 133-1 which contains a plurality of wiring lines 137-2 and a plurality of via-plugs 137-1. The wiring line 137-2 is for a signal line to transfer a signal to the plurality of devices, a power supply line or ground line which connects the plurality of devices and the power supply wiring layer section 132. The via-plug 137-1 connects between the wiring lines 37-2, or between the wiring lines 137-2 and between the devices. A connection section 138 of the wiring line 137-2 and the via-plug 137-1 is formed by the dual damascene method. The power supply wiring layer section 132 is formed onto the local wiring layer section 133 and is composed of a wiring layer 132-1 which contains a plurality of wiring lines 134-2 and a plurality of via-plugs 134-1. The via-plug 134-1 is connected with the local wiring layer section 133 and is especially called a via-plug 136 in this conventional example. The via-plug 134-1 connects the wiring lines 134-2. The wiring line 134-2 is a power supply line which connects the plurality of devices with the power supply or a ground line. A connection section 135 of the wiring line 134-2 and the via-plug 134-1 is formed by the dual damascene method.

By the way, a via-first method and a trench-first method are known in the dual damascene method. In the via-first method, it is necessary to fill a via-hole with BARC (Bottom Anti-Reflection Coating) for the reflection prevention in exposure, before a wiring line trench is formed after the via-hole is opened. Therefore, the via-first method is complex. In this way, the trench-first method is preferably used in which the processes are few. However, in the trench-first method, when a via-hole is to be formed by a photolithography technique, it is necessary to apply photo-resist on the semiconductor device which has a step for the wiring line trench and to expose a predetermined pattern. For this reason, in the pattern of the wiring line trench, it is difficult to appropriately adjust a focus because of the step. Especially, it is not possible to correctly expose a fine shape. Therefore, in an area where a pitch between the via-holes is narrow when the via-hole is small in size, the via-hole is generally formed by the via-first method, as in the local wiring layer section 133.

Hereinafter, the via-first method as one of the dual damascene methods will be described. As shown in FIG. 2A, an interlayer insulating film 103 is formed on a substrate 140, and a wiring line 110 of a first layer is formed in a stopper insulating layer 104 and a low dielectric constant insulating layer 105 on the interlayer insulating film 103. The wiring line 110 contains a wiring line conductor 109 of copper (Cu) and a barrier metal layer 108 of the tantalum/tantalum nitride (Ta/TaN) and has a damascene structure. The wiring line 110 is formed by a wiring line manufacturing process which is conventionally known. A stopper insulating film 114 is formed to cover the wiring line 110 and the low dielectric constant insulating layer 105. Subsequently, an interlayer insulating film 115 is formed to cover the stopper insulating film 114. Subsequently, a stopper insulating film 124 is formed to cover the interlayer insulating film 115. Then, a low dielectric constant insulating film 125 is formed to cover the stopper insulating film 124.

Next, as shown in FIG. 2B, a via-hole 107 is formed in the interlayer insulating film 115, the stopper insulating film 124 and the low dielectric constant insulating film 125, by using the photolithography process.

Next, as shown in FIGS. 2C-1 and 2C-2, the via-hole 107 is filled with organic material (for example, BARC) 142. A quantity of organic material 142, i.e., the height hA of organic material 142 in the via-hole 107 is determined based on a density of the via-holes 107 and other factors. In this example, the height hA is equal to the height of the stopper insulating film 124. FIG. 2C-2 shows a cross section of the wiring structure along the line A-A′ in FIG. 2C-1.

Next, as shown in FIGS. 2D-1 and 2D-2, a wiring line trench 117 is formed in the low dielectric constant insulating layer 125 by using the photolithography process. FIG. 2D-2 shows a cross section of the wiring structure along the line B-B′ in FIG. 2D-1.

Next, as shown in FIGS. 2E-1 and 2E-2, the organic material 142 is removed. Also, the stopper insulating film 114 in the bottom of the via-hole 107 and the stopper insulating film 124 in the bottom of the wiring line trench 117 are etched back and are removed. FIG. 2E-2 shows a cross section of the wiring structure along the line C-C′ in FIG. 2E-1.

Next, as shown in FIGS. 2F-1 and 2F-2, a barrier metal film 118 of Ta/TaN is formed to cover the surface of the low dielectric constant insulating layer 125, the side walls and bottom of the wiring line trench 117, the side walls and bottom of the via-hole 107. Subsequently, a seed conductor film 119a of Cu is formed to cover the barrier metal film 118. Subsequently, a conductor film 119b of Cu is formed to cover the seed conductor film 119a and to fill the wiring line trench 117 and the via-hole 107. FIG. 2F-2 shows a cross section of the wiring structure along the line D-D′ in FIG. 2F-1.

Next, as shown in FIGS. 2G-1 and 2G-2, an unnecessary portion of the barrier metal film 118, and a conductor layer 119 of the seed conductor film 119a and the conductor film 119b is removed from the surface of the low dielectric constant insulating layer 125 and a region above the wiring line trench 117, by a CMP (Chemical Mechanical Polishing) process. FIG. 2G-2 shows a cross section of the wiring structure along the line E-E′ in FIG. 2G-1.

Thus, a via-plug 120 of the barrier metal layer 118 and the conductor layer 119 is formed in the via-hole 107. Also, a wiring line 130 of the barrier metal layer 118 and the conductor layer 119 is formed in the wiring line trench 117. In this way, the wiring line and the via-plug are formed by the via-first method as one of the dual damascene methods as shown in FIGS. 2A to 2G-2. Here, the via-plug 120, and the wiring line 130 and the wiring line 110 correspond to the via-plug 137-1 and the wiring line 137-2 in FIG. 1, respectively.

Contrary to the via-first method, in the trench-first method as one of the dual damascene methods which is used for the power supply wiring layer section 132, first, the wiring line trench 117 is formed. The via-hole 107 is formed in a predetermined position in the bottom of the wiring line trench 117 by the photolithography process. The subsequent processes such as the processes of forming the barrier metal layer 118 and the conductor layer 119 are the same as those of the via-first method.

In FIGS. 2D-1 and 2D-2, the height of the organic material 142 is equal to the height of the stopper insulating film 124 in the via-hole 107. In the actual semiconductor device, the plurality of via-holes 107 are provided in a same layer, and there are a dense area where the many via-holes 107 are present and a sparse area where few via-holes 107 are present. The organic material 142 of a predetermined quantity per unit area of the surface is supplied onto the same layer. Therefore, if BARC is supplied such that the height of the organic material 142 is equal to the height of the stopper insulating film 124 in the dense area, the height of the organic material 142 is higher than the height of the stopper insulating film 124 in the sparse area. On contrary, if BARC is supplied such that the height of the organic material 142 is equal to the height of the stopper insulating film 124 in the sparse area, the height of the organic material 142 is lower than the height of the stopper insulating film 124 in the dense area. When the height of the organic material 142 is higher than the height of the stopper insulating film 124 in the via-hole 107, the following problem is caused.

FIGS. 3A-1 and 3A-2 are cross sectional views of a semiconductor device when the organic material is supplied such that the height of the organic material is higher than the height of the stopper insulating film. FIG. 3A-1 corresponds to FIG. 2C-1. FIG. 3A-2 is a cross sectional view of the wiring structure along the line F-F′ of FIG. 3A-1. The organic material 142′ fills the via-holes 107 to the height of the low dielectric constant film 125. At this time, as shown in FIGS. 3B-1 and 3B-2, the wiring line trench 117 is formed in the low dielectric constant insulating layer 125 by using the photolithography process. FIG. 3B-2 is a cross sectional view of the wiring structure along the line G-G′ of FIG. 3B-1. In this case, when the wiring line trench 117 is formed by the etching, etching resultant remainder substance adheres to the side of the organic material 142′ which protrudes in the wiring line trench 117, to form a fence (film) 145. This fence 145 is left after removing the organic material 142′. Therefore, the fence 145 obstructs the forming of the barrier metal film 118 and the seed conductor film 119a. As a result, problems such as increase of a resistance of the wiring line and break of the wiring line are caused, resulting in decrease of reliability.

On the other hand, when the height of the organic material 142 is lower than the height of the stopper insulating film 124 in the via-hole 107, the following problems are caused.

FIGS. 4A-1 to 4B-2 are cross sectional views showing the semiconductor device when the height of the organic material 142 is lower than the height of the stopper insulating film 124 in the via-hole 107. FIG. 4A-2 is a cross sectional view of the semiconductor device along the line H-H′ of FIG. 4A-1. As shown in FIG. 4B-1, the wiring line trench 117 is formed in the via-hole 107′ in the low dielectric constant insulating layer 125 by using the photolithography process. As a result, the state shown in FIG. 4B-2 is accomplished. FIG. 4B-2 is a cross sectional view of the semiconductor device along the line I-I′ of FIG. 4B-1. At this time, shoulder portions of the stopper insulating film 124′ and the interlayer insulating film 115 are etched in the via-hole 107′. Thus, the edge defect sections 146 are formed at the shoulder portions of the stopper insulating film 124′ and the interlayer insulating film 115. The edge defect section 146 appears especially conspicuously in the direction of the wiring line trench 117′. This is because the etching rate of the shoulder portion is larger than the etching rate of the other portion when the shoulder portion having a corner (i.e., the opening portion of the via-hole 107b′ in this case) is formed.

Next, as shown in FIGS. 4C-1 and 4C-2, the organic material 142″ is removed from the state shown in FIG. 4B-2. Then, the stopper insulating film 114 in the bottom of the via-hole 107′ and the stopper insulating film 124 in the bottom of the wiring line trench 117′ are etched back and are removed. Subsequently, the barrier metal film 118, the seed conductor film 119a, and the conductor film 119b are formed. An unnecessary portion of the barrier metal film 118, the seed conductor film 119a and the conductor film 119b are removed from the surface of the low dielectric constant insulating layer 125, and a region above the wiring line trench 117′ by the CMP to form a via-plug 120 and a wiring line 130. FIG. 4C-2 is a cross sectional view showing the semiconductor device along J-J′ line of FIG. 4C-1. In this case, the edge defect portions 146 increase a cross section of the wiring line 130 in the length direction of the wiring line 130. That is, it causes the increase of the capacitance between the wiring lines.

It is important to maintain the reliability of the wiring line when the miniaturization of the semiconductor device during recent years is carried forwarded. Specifically, it is necessary to prevent the migration or diffusion of copper into the insulating film by forming a thick barrier metal film, and to make the height of the organic material lower than the height of the cap insulating layer by decreasing the amount of the organic material filled in the via-hole from the reason described with reference to FIGS. 3A-1 to 3B-2. In this case, the problems are caused that the barrier metal film is thick so that the resistance of the wiring line increases and the edge defect sections 146 are formed described with reference to FIGS. 4A-1 to 4C-2.

FIG. 5 is a cross sectional view showing the wiring structure of the semiconductor device which contains the edge defect sections of FIGS. 4A-1 to 4C-2. The semiconductor device 101a is composed of a device section 131a, a local wiring layer section 133a and a power supply wiring layer section 132a. The device section 131a, the local wiring layer section 133a and the power supply wiring layer section 132a are basically the same as the device section 131, the local wiring layer section 133 and the power supply wiring layer section 132 shown in FIG. 1. However, in the local wiring layer section 133a, the pitch between the via-plugs 137a-1 becomes narrow. Also, as described with reference to FIGS. 4A-1 to 4C-2, the edge defect sections 146a-1 and 146a-2 are formed. Here, the edge defect section 146a-2 differs from the edge defect section 146a-1 in the direction by 90 degrees and the edge defect shown in FIGS. 4C-1 and 4C-2 has occurred to the direction perpendicular to the figure.

In this case, the pitch between the via-plugs 137a-1 is made small and the distance between the edge defect sections 146a becomes near. In addition, the cross section of the wiring line in the length direction increases due to the edge defect sections 146a. The increase of the capacitance between the wiring lines due to the forming of the edge defect sections 146a around the via-plug can not be ignored.

In conjunction with the above description, a semiconductor device and a manufacturing method are disclosed in Japanese Laid Open Patent Application (JP-P2001-156168). The semiconductor device of this conventional example has a semiconductor substrate and a plurality of wiring layers. A plurality of devices are formed on the semiconductor substrate. A plurality of wiring layers are formed above the semiconductor substrate. The plurality of wiring layers are composed of signal lines of copper to connect between the plurality of devices and power supply lines and ground lines of copper to connect the plurality of devices with the power supply. The connections of the signal line, the power supply line and the ground line in the plurality of wiring layers are accomplished by via-contacts which are formed under the signal line, the power supply line and the ground line. Here, the signal line and a first via-contact formed under the signal line are formed by the single damascene process, and the first via-contact is formed of tungsten. The power supply line, the ground line, and the second via-contacts formed under the power supply line or the ground line are formed by the dual damascene process. The area of the second via-contact is formed to be larger by a predetermined ratio than the area of the first via-contact.

### SUMMARY OF THE INVENTION

An object of the present invention is to provide a semiconductor device and a method of manufacturing the same, in which reliability of wiring lines and via-plugs in a local wiring layer can be improved.

Another object of the present invention is to provide a semiconductor device and a method of manufacturing the same, in which increase of a capacitance between wiring lines and a resistance of the wiring line in a local wiring layer can be prevented.

Another object of the present invention is to provide a semiconductor device and a method of manufacturing the same, in which reliability of an operation of the semiconductor device can be improved.

Another object of the present invention is to provide a semiconductor device and a method of manufacturing the same, in which the number of processes can be decreased while keeping a low resistance of a via-plug in a power supply wiring layer.

In an aspect of the present invention, a semiconductor device includes a first wiring layer section formed above a semiconductor substrate; and a second wiring layer section formed on the first wiring layer section. The first wiring layer section includes a first interlayer insulating film; a plurality of first via-plugs formed in the first interlayer insulating film to be separated from each other by a first distance; and a plurality of first wiring lines formed on the plurality of first via-plugs in the first interlayer insulating film and connected with the plurality of first via-plugs. The second wiring layer section includes a second interlayer insulating film; a plurality of second via-plugs formed in the second interlayer insulating film and separated from each other by a second distance which is longer than the first distance; and a plurality of second wiring lines formed on the plurality of second via-plugs in the second interlayer insulating film and connected with the plurality of second via-plugs, respectively. The plurality of first via-plugs, the plurality of first wiring lines, the plurality of second via-plugs and the plurality of second wiring lines contain metal containing copper. The first wiring layer section has a single damascene structure, and the second wiring layer section is a dual damascene structure.

Here, the first wiring layer section may include a plurality of layers, each of which may include the plurality of first via-plugs and the plurality of first wiring lines formed in the first interlayer insulating film. The second wiring layer section may include a plurality of layers, each of which may include the plurality of second via-plugs and the plurality of second wiring lines formed in the second interlayer insulating film.

In this case, the first distance is desirably set such that a via density meets a predetermined condition, the via density indicating as a number of the first via-plugs per unit area. The predetermined condition is that a capacitance between the first wiring lines between becomes smaller than a capacitance between the first wiring lines when the first wiring layer section is formed to have the dual damascene structure. It is desirable the via density is equal to or more than 1/μm² in the predetermined condition.

Also, the first distance may 0.5 μm, and a diameter of each of the plurality of first via-plugs may be equal to or less than 0.4 μm.

Also, another aspect of the present invention is achieved by (a) forming a first insulating film above a semiconductor substrate; by (b) forming a plurality of first via-plugs in the first insulating film by a single damascene method, the plurality of first via-plugs being formed of metal containing copper and being separated from each other by a first distance; by (c) forming a second insulating film on the first insulating film and the plurality of first via-plugs; by (d) forming a plurality of first wiring lines in the second insulating film by a single damascene method, the plurality of first wiring lines being formed of metal containing copper and being separated from each other by the first distance; by (e) forming a third insulating film on the second insulating film and the plurality of first wiring lines; and by (f) forming a plurality of second wiring lines and a plurality of second via-plugs connected with the plurality of second wiring lines in the third insulating film by a dual damascene method, the plurality of second wiring lines and the plurality of second via-plugs being formed of metal containing copper and separated from each other by a second distance longer than the first distance.

Here, it is desirable that the dual damascene method is a trench-first method.

Also, the method of manufacturing the semiconductor device may further include repeating the (a) forming step to the (d) forming step before the (e) forming step; and repeating the (e) forming step and the (f) forming.

In this case, the first distance is desirably set such that a via density meets a predetermined condition, the via density indicating as a number of the first via-plugs per unit area. The predetermined condition is that a capacitance between the first wiring lines between becomes smaller than a capacitance between the first wiring lines when the first wiring layer section is formed to have the dual damascene structure.

In this case, it is desirable that the via density is equal to or more than 1/μm² in the predetermined condition.

Also, the first distance may be 0.5 μm, and a diameter of each of the plurality of first via-plugs may be equal to or less than 0.4 μm.

### BRIEF DESCRIPTION OF THE DRAWINGS

FIG. 1 is a cross sectional view showing the wiring structure of a conventional semiconductor device;

FIGS. 2A and 2B, and 2C-1 to 2G-2 are cross sectional views showing a wiring structure of a conventional semiconductor device manufactured by a via-first method;

FIGS. 3A-1 to 3B-2 are cross sectional views showing a wiring structure of the semiconductor device when a via-hole is fully filled with organic substance;

FIGS. 4A-1 to 4C-2 are cross sectional views showing a wiring structure of the semiconductor device when the height of the organic substance is lower than the height of a stopper insulating layer;

FIG. 5 is a cross sectional view showing the semiconductor device which contains edge defect portions;

FIG. 6 is a cross sectional view showing a semiconductor device according to an embodiment of the present invention;

FIGS. 7A to 7L are cross sectional views showing a wiring structure of the semiconductor device manufactured by a single damascene structure to have wiring lines and via-plugs;

FIGS. 8A to 8D are cross sectional views showing the wiring structure of the semiconductor device showing the wiring lines and the via-plugs of the single damascene structure and a dual damascene structure; and

FIG. 9 is a graph showing a relationship between the single damascene structure and the dual damascene structure.

### DESCRIPTION OF THE PREFERRED EMBODIMENTS

Hereinafter, a semiconductor device and a method of manufacturing the same of the present invention will be described with reference to the attached drawings.

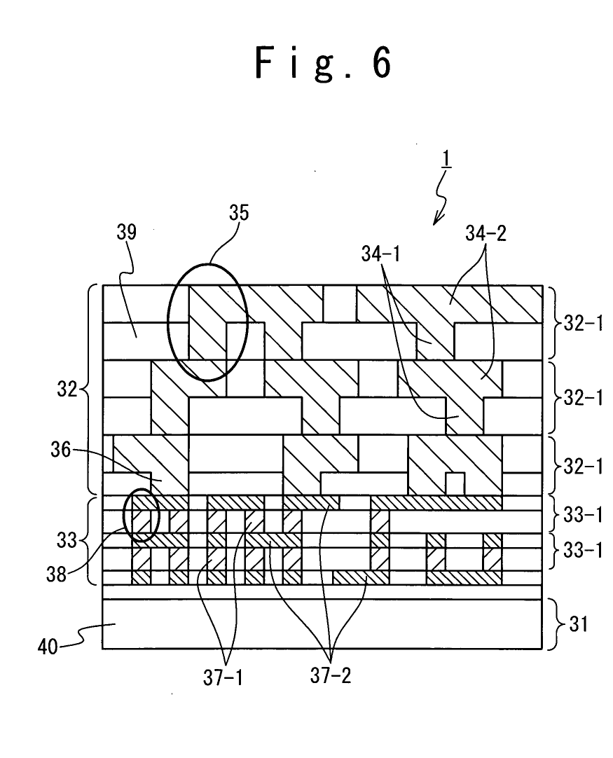

First, the structure of the semiconductor device according to the first embodiment of the present invention will be described. Referring to FIG. 6, the semiconductor device 1 is composed of a device section 31, a local wiring layer section 33 and a power supply wiring layer section 32.

The device section 31 is composed of a plurality of devices (not shown) formed on the semiconductor substrate 40.

The local wiring layer section 33 is formed on the device section 31 and is composed of a plurality of wiring layers 33-1 which contain a plurality of wiring lines 37-2 (a part of them is shown in the figure) and a plurality of via-plugs 37-1 (a part of them is shown in the figure). The wiring line 37-2 is a signal line used to connect a signal to the plurality of devices, a power supply line or a ground line is used to connect the plurality of devices and the power supply wiring layer section 32. The via-plug 37-1 connects between the wiring lines 37-2 or between the wiring line 37-2 and the device. The wiring line 37-2 is formed of a barrier metal film of tantalum/tantalum nitride and a copper film surrounded by the barrier metal film. A connection section 38 is formed from a part of wiring line 37-2 and the via-plug 37-1 by a single damascene method. The connection section which is formed from a part of another wiring line 37-2 and another via-plug 37-1 in the local wiring layer section 33 is also same.

The power supply wiring layer section 32 is formed on the local wiring layer section 33 and is composed of a plurality of wiring layers 32-1 which contain a plurality of wiring lines 34-2 (a part of them is shown in the figure) and a plurality of via-plugs 34-1 (a part of them is shown in the figure). The plurality of wiring lines 34-2 are power supply lines which connects the plurality of devices to a power supply or ground lines. The via-plug 34-1 connects between the wiring lines 34-2. The wiring line 34-2 and the via-plug 34-1 are formed of a barrier metal film of tantalum/tantalum nitride and a copper film surrounded by the barrier metal film. The connection section 35 is formed from a part of the wiring line 34-2 and the via-plug 34-1 by a trench-first method as one of the dual damascene method. A connection section which is formed from a part of another wiring line 34-2 and another via-plug 34-1 in the power supply wiring layer section 32 is also same. The via-plug 34-1 connected with the local wiring layer section 33 is especially referred to as a via-plug 36.

The structure of the wiring line 37-2 and the via-plug 37-1 which have the single damascene structure in the local wiring layer section 33 will be described.

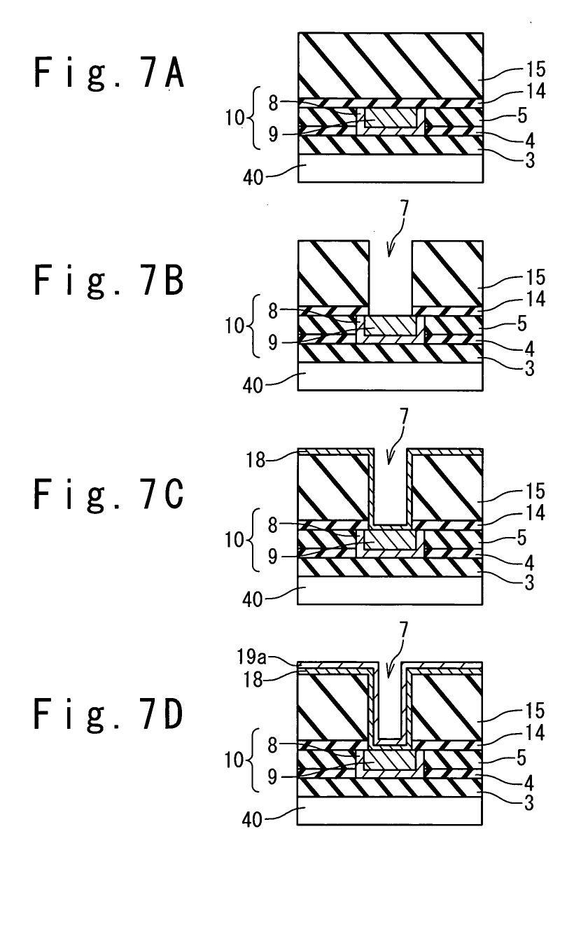

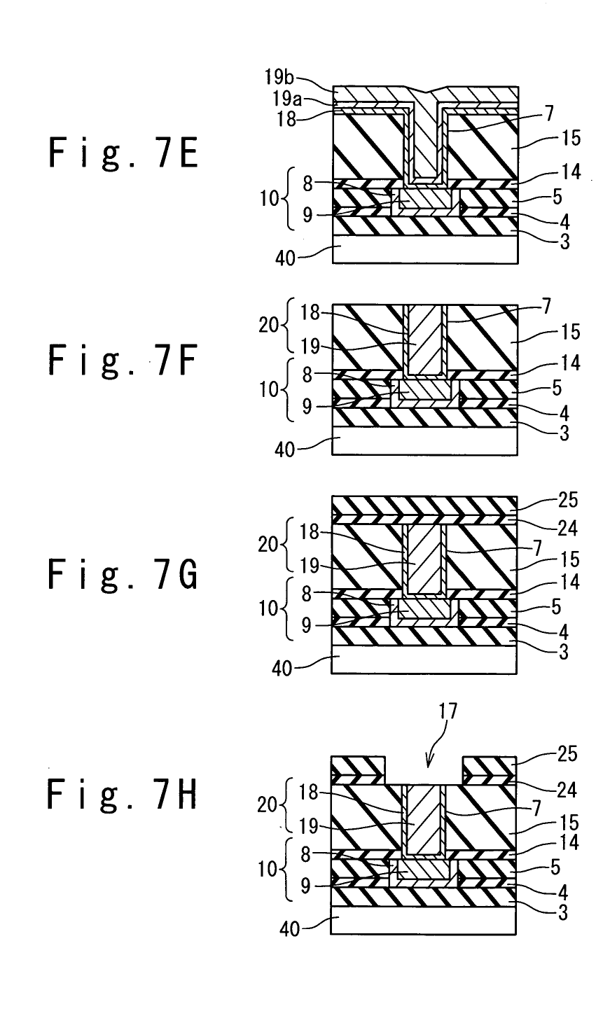

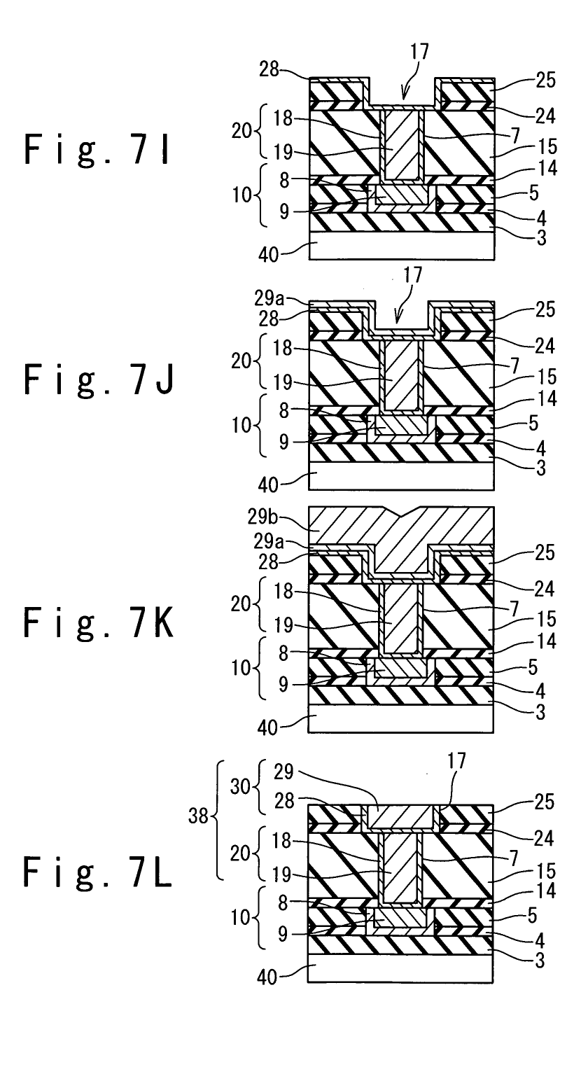

Referring to FIG. 7L, the wiring line and the via-plug which have the single damascene are formed on a substrate 40, and are composed of a first wiring line 10 which contains an interlayer insulating layer 3, a cap insulating layer 4, a low dielectric constant insulating layer 5, a barrier metal layer 8 and a conductor section 9, a via-contact 20 which contains a cap insulating layer 14, an interlayer insulating layer 15, a barrier metal layer 18 and a conductor section 19, and a second wiring line 30 which contains a cap insulating layer 24, a low dielectric constant insulating layer 25, a barrier metal layer 28 and a conductor section 29.

The substrate 40 is the semiconductor substrate with a multi-layer structure of insulating films in which a plurality of wiring line structures and the devices are embedded.

The interlayer insulating layer 3 is formed to cover the substrate 40. The interlayer insulating layer 3 is an insulating film formed by a CVD method or a spin coat method to isolate between the wiring lines, between the wiring line and the device, and between the devices. A material of a low dielectric constant is used for the interlayer insulating layer 3 to decrease a parasitic capacitance between the wiring lines. In this embodiment, a low dielectric constant film of an organic polymer which has a relative dielectric constant equal to or less than 3.0 is used.

The cap insulating layer 4 is formed to cover the interlayer insulating layer 3. The cap insulating layer 4 is an insulating film formed on the interlayer insulating film 3 by the CVD method and the spin coat method. The cap insulating layer 4 is used to protect the interlayer insulating film 3 in the photolithograph process to form a wiring line trench for the first wiring line 10. In this embodiment, the cap insulating layer 4 is formed of silicon carbide nitride (SiCN) and has the film thickness of approximately 100 nm, for example.

The low dielectric constant insulating layer 5 is formed to cover the cap insulating layer 4. The low dielectric constant insulating layer 5 is an insulating film formed by the CVD method or the spin coat method to isolate between the wiring lines, between the wiring line and the device, and between the devices. A material of a low dielectric constant can be used for the low dielectric constant insulating layer 5 in order to decrease a parasitic the capacitance between the wiring lines. In this embodiment, a low dielectric constant film of an organic polymer group which has a low relative dielectric constant equal to or less than 3.0 is used. For example, the film thickness is approximately 200 nm.

The first wiring line 10 is formed to fill the wiring line trench which passes through the cap insulating layer 4 and the low dielectric constant insulating layer 5 from the surface of the interlayer insulating layer 3. The first wiring line 10 contains the barrier metal layer 8 and the conductor section 9.

The barrier metal layer 8 is formed of a metal film by a sputtering method to cover side walls and a bottom of the wiring line trench. The barrier metal layer 8 is used to prevent diffusion of the conductor section 9 into the low dielectric constant insulating layer 5 and aggregation of the conductor section 9. The barrier metal layer 8 is formed of high melting point metal or nitride. In this embodiment, the barrier metal layer 8 is a lamination film of tantalum/tantalum nitride (Ta/TaN), and has the film thickness is approximately 30 nm, for example.

The conductor section 9 is formed of metal by the sputtering method and a plating method to fill the wiring line trench in which the barrier metal layer 8 is formed. For a contact, this portion is formed of metal with low resistivity, i.e., metal containing copper such as copper and copper-aluminum. In this embodiment, copper (Cu) is used. The first wiring line 10 is connected to the via-contact 20 on the side opposite to the substrate 40. For example, the depth and width of the first wiring line 10 are 300 nm and 300 nm, respectively.

The cap insulating layer 14 is formed to cover the low dielectric constant insulating layer 5 and the first wiring line 10. The material, manufacturing method and film thickness are same as those of the cap insulating layer 4.

Also, the interlayer insulating layer 15 is formed to cover the cap insulating layer 14. The material and the manufacturing method are same as those of the interlayer insulating layer 3. For example, the film thickness is approximately 400 nm.

The barrier metal layer 18 is formed to cover the side walls and a bottom of the via-hole 7. The material, manufacturing method and film thickness are same as those of the barrier metal layer 8.

The conductor section 19 is formed to fill the via-hole 7 in which the barrier metal layer 18 is formed. The material and the manufacturing method are same as those of the conductor section 9. For example, the size of the via-hole 32 has the width of 200 nm and the depth of 500 nm. The conductor section 19 constitutes the via-contact 20 together with the barrier metal layer 18.

The cap insulating layer 24 is formed to cover the interlayer insulating layer 15. The material, the manufacturing method and the film thickness are same as those of the cap insulating layer 4.

The low dielectric constant insulating layer 25 is formed to cover the cap insulating film 24. The material, the manufacturing method and the film thickness are same as those of the low dielectric constant insulating layer 5.

The barrier metal layer 28 is formed to cover the side walls and the bottom of the wiring line trench 17 which passes through the cap insulating film 24 and the low dielectric constant insulating layer 25 from the surface of the interlayer insulating layer 15 and the via-contact 20. The material, the manufacturing method and the film thickness are same as those of the barrier metal film 8. In this case, the wiring line trench 17 is a trench to form the second wiring line 30.

The conductor section 19 is formed to fill the wiring line trench 17 in which the barrier metal film 28 is formed. The material, the manufacturing method and the film thickness are same as those of the conductor section 9.

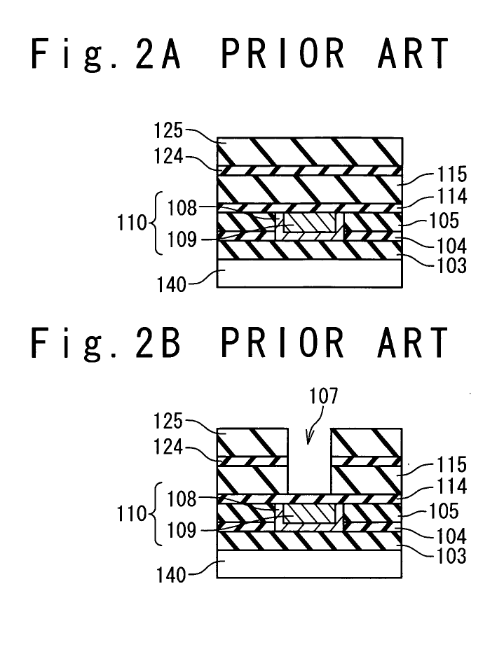

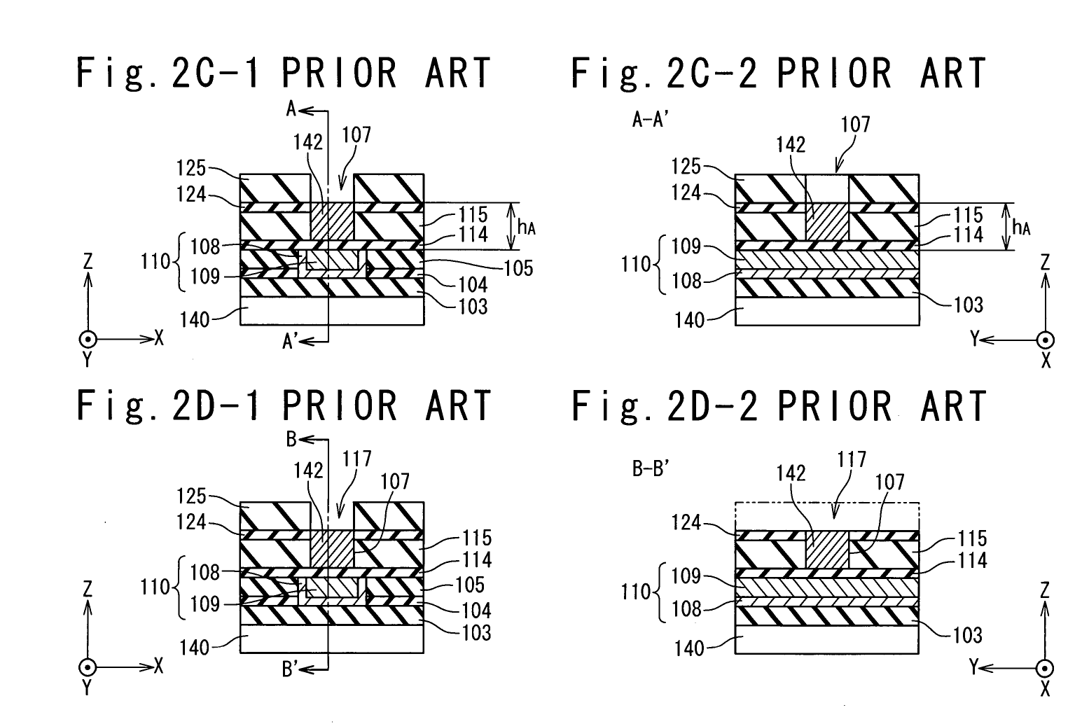

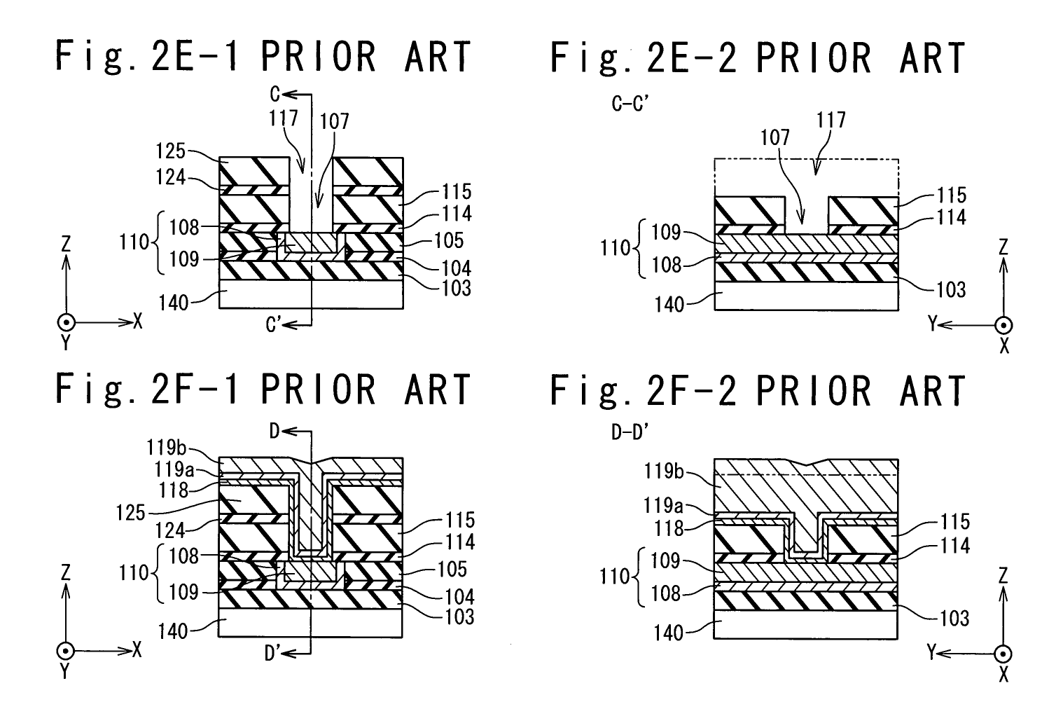

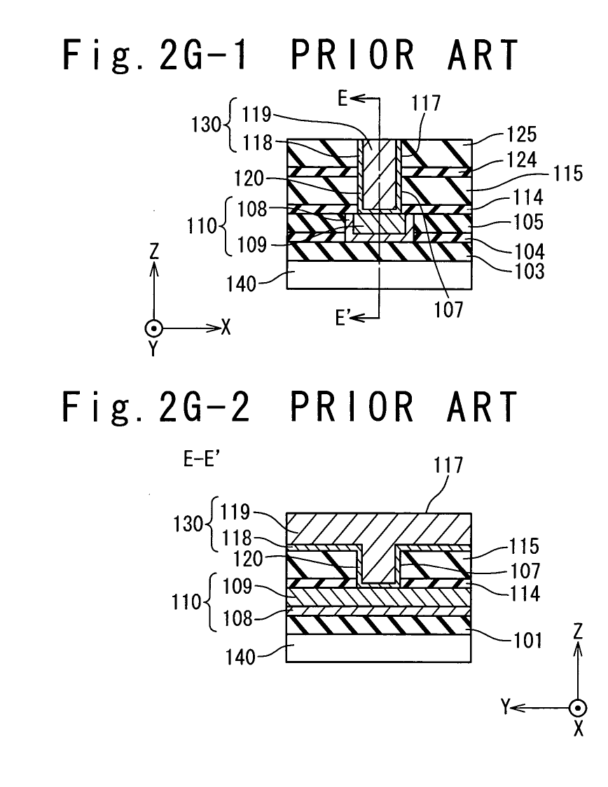

Referring to FIG. 6, the structure of the wiring line 34-2 and the via-plug 34-1 which have the dual damascene structure in the power supply wiring layer section 32 is the same as described with reference to FIGS. 2A to 2G-2, except that the trench-first method is used. Therefore, the description is omitted. Also, the via-first method may be used.

In this case, the interlayer insulating layer in the power supply wiring layer section 32 is an insulating film formed by the CVD method or the spin coat method to isolate between the wiring lines. The wiring layer in this portion has only few influences of the capacitance between the wiring lines. For this reason, an insulating film of the inorganic group such as silicon dioxide is used as the interlayer insulating layer. In this embodiment, silicon dioxide is used. Because such an insulating layer has strong mechanical strength, the damage of the semiconductor device can be prevented at the time of the assembly.

In the present invention, the single damascene structure with the via-plug of copper is adopted without adopting the dual damascene structure in the local wiring layer section 33. The reason will be described below.

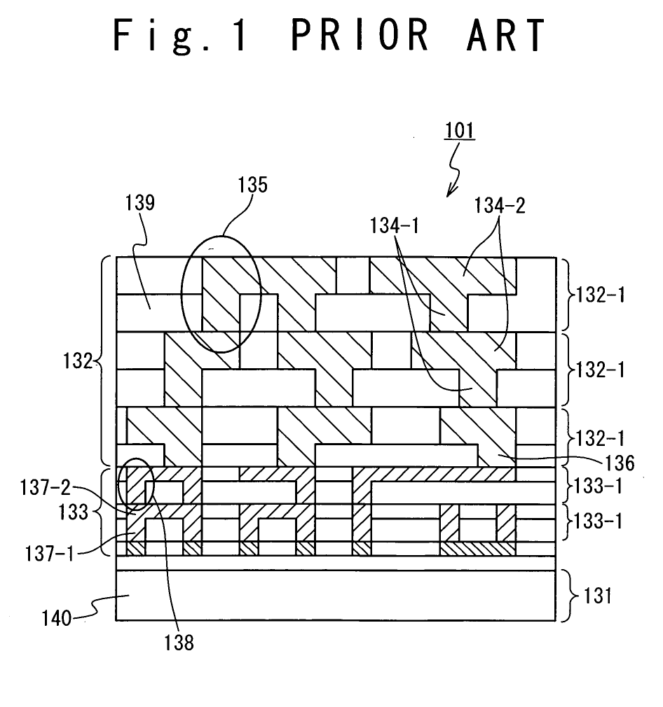

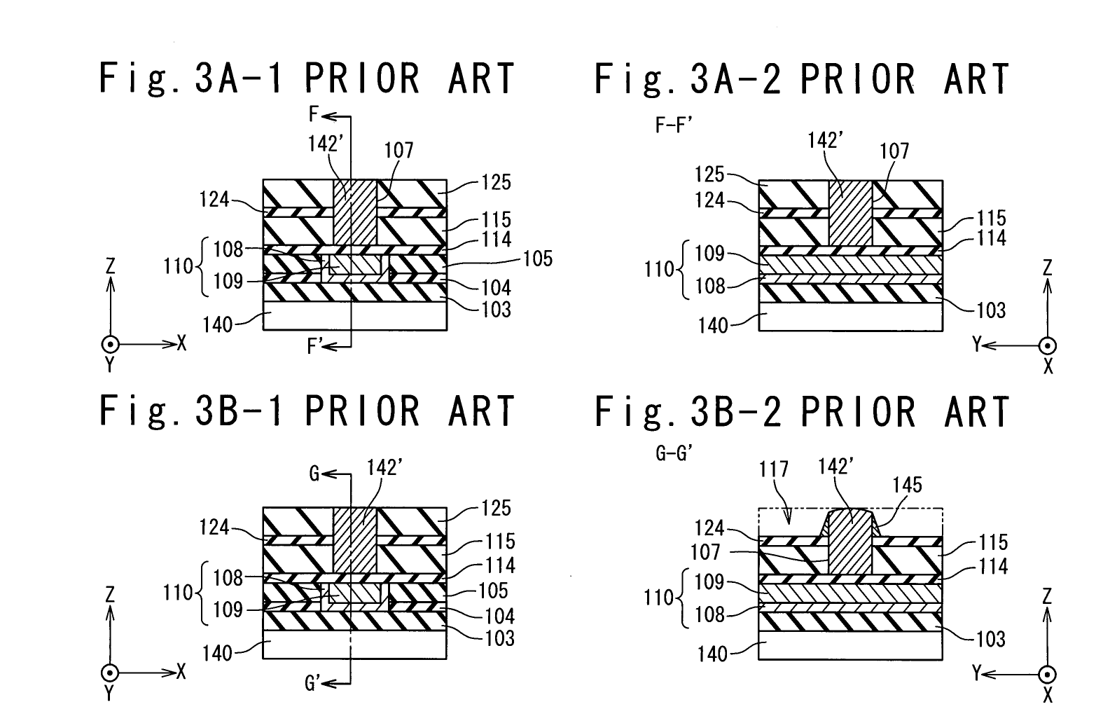

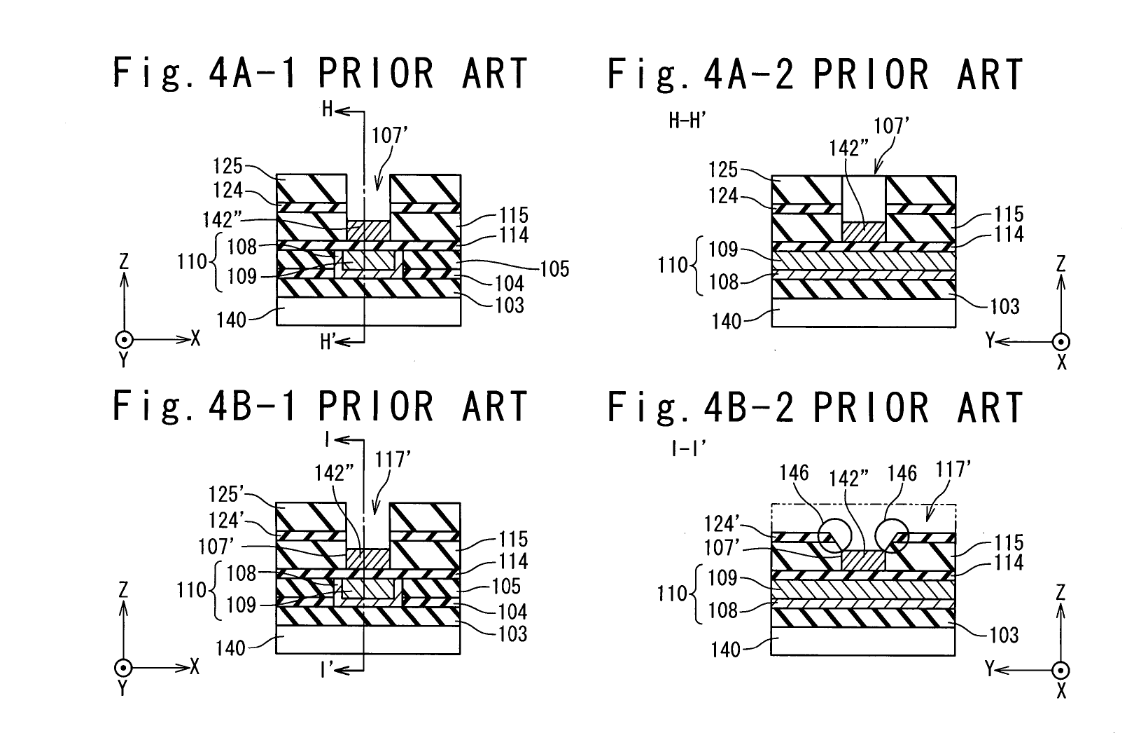

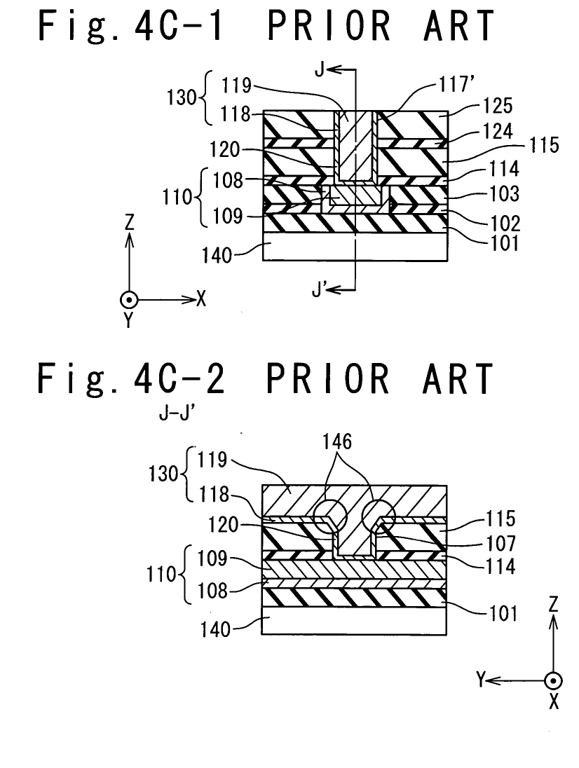

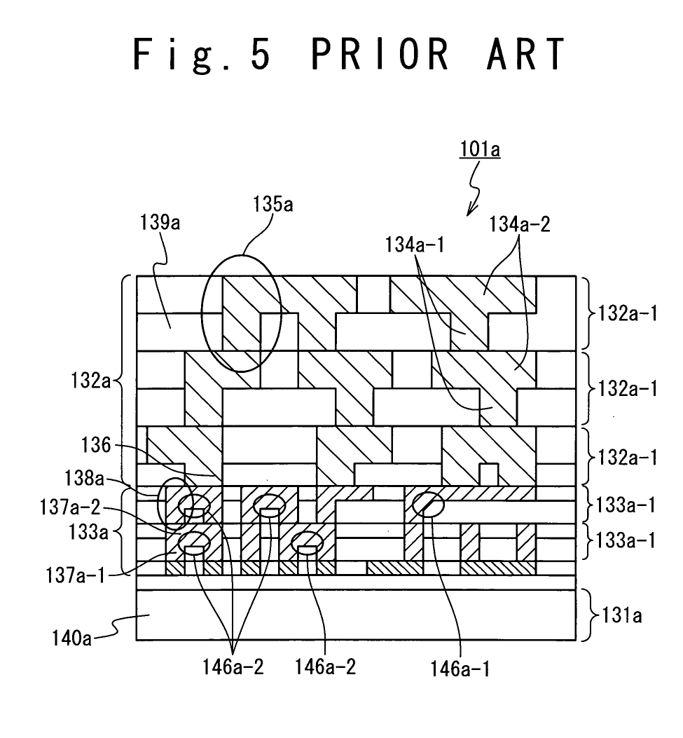

When the conventional method which the local wiring layer section 33 with the dual damascene structure is formed by the via-first method, in processes of FIGS. 2C-1 and 2C-2, the thicknesses of ARC (Anti-Reflection Coating: organic material 142) to be filled, i.e., the heights hA in FIG. 2C-1 and FIG. 2C-2 are different between an isolated via-hole that there is not another via-hole in the neighborhood (hereinafter, to be referred to as an “isolated via-hole”) and a via-hole that there are many other via-hole in the neighborhood (hereinafter, to be referred to as a “dense via-hole”). This is based on the following reason. That is, a constant ARC per unit area of the surface of the wiring layer is supplied onto the same wiring layer. Therefore, the isolated via-hole is filled with a lot of ARC. However, the dense via-hole is filled with ARC less than in the isolated via-hole. In such a case, the upper limit of the height hA of the ARC is determined based on the height of the isolated via-hole. That is, in order to prevent the fence 145 shown in FIG. 3B-2 from being formed, the height hA of ARC in the region where there is the isolated via-hole is set to be lower than the film thickness h of the insulating layer between the difference layers (i.e., the film thickness of the stopper insulating film 124+the film thickness of the interlayer insulating layer 115 in FIGS. 3A-1 to 3B-2). In this case, in the dense via-hole of the same wiring layer, when the film thickness of the insulating layer between the difference layers is h μm, and the number of the dense via-holes per unit area is n/μm² (i.e., the number of the via-plugs per unit area, hereinafter to be referred to as a “via density”), the height hA of ARC is about h/n. Supposing that the minimum pitch of the wiring line is L μm, the pitch of the dense via-hole is L μm. When the via-plug is formed in such a via-hole, the above-mentioned edge defect section is formed as shown in FIG. 4C-2.

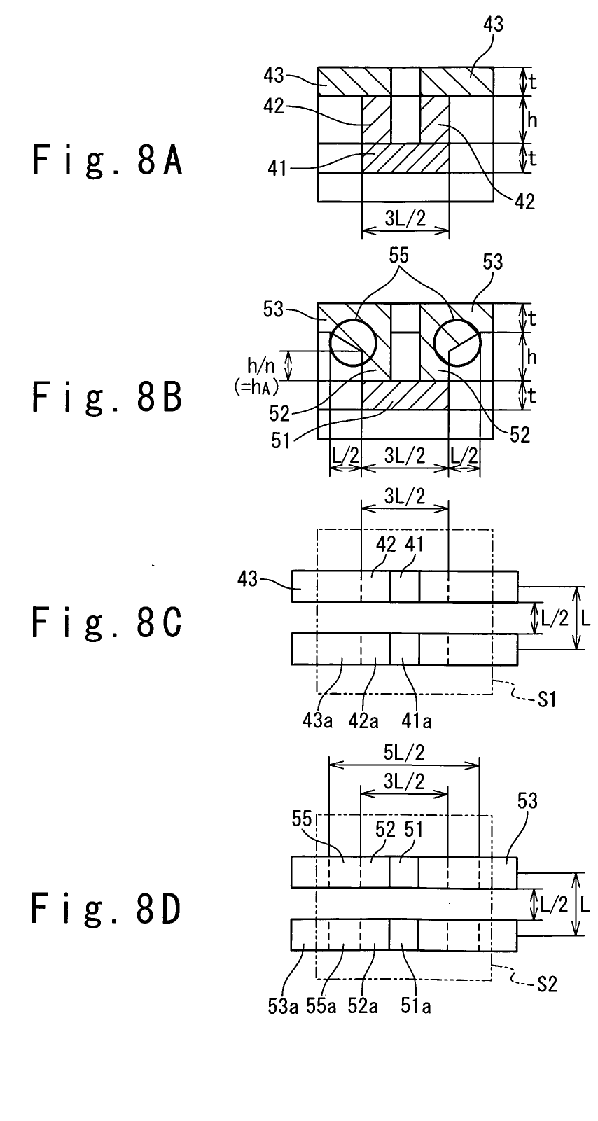

FIGS. 8A and 8C are a cross sectional view and a plan view showing the wiring line and the via-plug of the single damascene structure, and FIGS. 8B and 8D are a cross sectional view and a plan view showing the wiring line and the via-plug of the dual damascene structure by the via-first method.

Referring to FIG. 8B, the dual damascene structure is composed of a wiring line 51 in a first layer, a via-plug 52, a wiring line 53 in the second layer and edge defect sections 55. The wiring line 51 and wiring line 53 have the film thickness of t μm and the via-plug 52 has the height of h μm. Also, from the above-mentioned consideration, the height of the edge defect section 55 (i.e., the height hA of the ARC) is about h/n. Referring to FIG. 8D, it is supposed that a set of a wiring line 53a (containing the edge defect section 55a), a via-plug 52a, a wiring line 51a, a via-plug 52a and a wiring line 53a (containing the edge defect section 55a) is formed in parallel to a set of the wiring line 53 (containing the edge defect section 55), the via-plug 52, the wiring line 51, the via-plug 52, and the wiring line 53 (containing the edge defect section 55). Such a structure is typical in the semiconductor device like a memory such as a DRAM and an SRAM.

Supposing that a wiring line pitch is L μm, a wiring line width is L/2 μm, and a distance between the wiring lines is L/2 μm, a capacitance between the wiring lines in a portion surrounded by the dotted line (CD/ε: ε is a dielectric constant of the insulating layer between the different layers) is:

(A) in case of the dual damascene structure,

$$\begin{matrix}CD / ϵ = [ 2 * \{ ( t + h ) * ( L / 2 ) \} + t * ( 3 L / 2 ) ] / ( L / 2 ) + \\ [ \{ ( h - h / n ) * ( L / 2 ) \} / 2 ] * 2 \\ = 5 t + 2 h + h * ( 1 - 1 / n )\end{matrix} \qquad ( 1 )$$

On the other hand, with reference to FIG. 8A, the single damascene structure is composed of a wiring line 41 in a first layer, a via-plug 42 and a wiring line 43 in a second layer. The wiring line 41 and wiring line 43 have the film thickness of t μm and the via-plug 42 has the height of h μm. Referring to FIG. 8C, like the case of FIG. 8D, it is supposed that a set of a wiring line 43a, a via-plug 42a, a wiring line 41a, a via-plug 42a and a wiring line 43a is formed in parallel to the set of the wiring line 43, the via-plug 42, the wiring line 41, the via-plug 42 and the wiring line 43. Supposing that a wiring line pitch is L μm, a wiring line width is L/2 μm, and a distance between the wiring lines is L/2 μm, the capacitance between the wiring lines in a portion surrounded by the dotted line (CS/ε: 68 is a dielectric constant of the insulating layer of the different layers) is:

(B) in case of the single damascene structure,

$$\begin{matrix}CS / ϵ = [ 2 * \{ ( t + h ) * L / 2 \} + t * ( 3 L / 2 ) ] / ( L / 2 ) \\ = 5 t + 2 h\end{matrix} \qquad ( 2 )$$

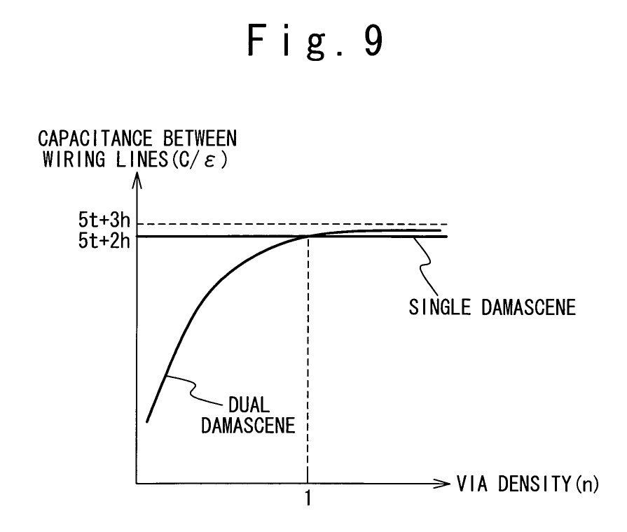

FIG. 9 shows graphs showing a case of the equation (1) and a case of the equation (2). The vertical axis is the capacitance (C/ε) between the wiring lines and the horizontal axis is the via density n. In case of the dual damascene structure, the capacitance between the wiring lines increases when the via density n increases, i.e. the pitch between the via-plugs becomes narrow. However, in case of the single damascene structure, the capacitance between the wiring lines does not depend on the via density. In other words, it is preferable to adopt the single damascene structure when the via density n is larger than “1”, that is, when the capacitance between the wiring lines in the dual damascene structure is larger than in the single damascene method.

It could be understood from FIG. 9 and the equations (1) and (2) that the capacitance between the wiring lines in the single damascene structure falls below that of the dual damascene structure in case of n equal to or more than 1. That is, the single damascene structure is preferable when the via density is n≧1.

Moreover, when t=0.3 μm and h=0.4 μm are used as typical values in the semiconductor device like the memory such as the DRAM and SRAM, n≧25 under a demand from the design that the capacitance between the wiring lines below 0.18 fF/μm, and the pitch become 0.4 μm.

In the present invention, when the wiring line in the local wiring layer section of the semiconductor device is made thin so that the via density n becomes large, the capacitance between the wiring lines can be more suppressed by adopting the single damascene structure, compared with a case of the dual damascene structure.

Next, the method of manufacturing the local wiring layer section 33 of the semiconductor device of the present invention will be first described. Here, the method of manufacturing the wiring lines and via-plug with the single damascene structure for one layer will be described. FIGS. 7A to 7L are the cross sectional views showing the method of manufacturing the wiring lines and via-plug with the single damascene structure in the semiconductor device.

In FIG. 7A, a wiring line 10 in a first layer is formed in the stopper insulating layer 4 and the low dielectric constant insulating layer 5 on the interlayer insulating film 3 which is formed on the substrate 40, on which a plurality of the semiconductor devices are formed. The wiring line 10 contains a wiring line 9 of copper (Cu) and a barrier metal layer 8 of tantalum/tantalum nitride (Ta/TaN) and has a damascene structure. The wiring line 10 is formed by the wiring line manufacturing process which is conventionally known. A stopper insulating film 14 is formed to cover the wiring line 10 and the low dielectric constant insulating layer 5. Subsequently, an interlayer insulating film 15 is formed to cover the stopper insulating film 14.

Next, as shown in FIG. 7B, a via-hole 7 is formed in the stopper insulating film 14 and the interlayer insulating film 15 by using a photolithography process. Next, as shown in FIG. 7C, a barrier metal film 18 of Ta/TaN is formed to cover the surface of the interlayer insulating layer 5 and the side walls and bottom of the via-hole 7 by a sputtering method. Thus, the via-hole 7 is formed at this time. Subsequently, as shown in FIG. 7D, a seed conductor film 19a of Cu is formed to cover the barrier metal film 18. Subsequently, as shown in FIG. 7E, a conductor film 19b of Cu is formed to cover the seed conductor film 19a and to fill the via-hole 7. As shown in FIG. 7F, an unnecessary portion of the barrier metal film 18, the seed conductor film 19a and the conductor film 19b on the surface of the interlayer insulating layer 15 and above the via-hole 7 are removed by CMP (Chemical Mechanical Polishing). In this way, a via-plug 20 (the via-contact) of the barrier metal layer 18 and the conductor layer 19 (19a and 19b) is formed.

Next, as shown in FIG. 7G, a stopper insulating film 24 is formed to cover the via-plug 20 and the interlayer insulating film 15. Subsequently, a low dielectric constant insulating film 25 is formed to cover the stopper insulating film 24. Then, as shown in FIG. 7H, a wiring line trench 17 in a second layer is formed in the stopper insulating film 24 and the low dielectric constant insulating film 25 by using the photolithography process. Next, as shown in FIG. 7I, a barrier metal film 28 of Ta/TaN is formed to cover the low dielectric constant insulating layer 25 and the side walls and bottom of the wiring line trench 17 by the sputtering method. Thus, the wiring line trench 17 is formed at this time. Subsequently, as shown in FIG. 7J, a seed conductor film 29a of Cu is formed to cover the barrier metal film 28. Then, as shown in FIG. 7K, a conductor film 29b of Cu is formed to cover the seed conductor film 29a and to fill the via-plug 17. Subsequently, as shown in FIG. 7L, an unnecessary portion of the barrier metal film 28, the seed insulating film 29a and the conductor film 29b on the surface of the low dielectric constant insulating layer 25 and above the wiring line trench 17 is removed by the CMP. In this way, a wiring line 30 of the barrier metal layer 28 and the conductor layer 29 (29a and 29b) is formed. The wiring line 30 and the via-plug 20 correspond to a connection section 38 (formed by the single damascene method in FIG. 6).

The wiring line and the via-plug with the single damascene structure for one wiring layer 33-1 are formed by the manufacturing method shown in FIGS. 7A to 7L. It should be noted that the via-plug 20, and the wiring line 10 and wiring line 30 in FIG. 7I correspond to the via-plug 37-1 and the wiring line 37-2 in FIG. 6, respectively. The other wiring layer 33-1 is laminated in the same way.

The description of the manufacturing method of the via-plug 36 is omitted, because the via-plug 36 can be formed by using the above-mentioned single damascene method or the conventional dual damascene method. Also, the description of the manufacturing method of the power supply wiring layer section 32 is omitted because the power supply wiring layer section 32 can be formed by using the previously mentioned dual damascene method (the trench-first method) except that an inorganic insulating film such as silicon oxide is used as the interlayer insulating layer.

By adopting the single damascene structure in the present invention, the fine wiring line can be formed stably. Thereby, it is not required to form the thick barrier metal film in the local wiring line section in which the pitch between the wiring lines is short and the wiring line is fine, resulting in reduction of the wiring line resistance.

Also, because the dual damascene structure is adopted for the power supply wiring layer section, the resistance of the via-plug can be kept low and the number of processes can be made less.

In addition, because the inorganic insulating film such as silicon oxide can be used as the interlayer insulating layer in the power supply wiring layer section, the mechanical strength is improved and it is possible to prevent the damage of the semiconductor device at the time of the assembly.

In the present invention, even when the wiring line of the semiconductor device is made fine in the local wiring layer section and the via density n is made large, the capacitance between the wiring lines can be suppressed by adopting the single damascene structure, compared with the case of the dual damascene structure.

What is claimed is:

1. A semiconductor device comprising:
a first wiring layer section formed above a semiconductor substrate; and
a second wiring layer section formed on said first wiring layer section,
wherein said first wiring layer section comprises:
a first interlayer insulating film;
a plurality of first via-plugs formed in said first interlayer insulating film to be separated from each other by a first distance; and
a plurality of first wiring lines formed on said plurality of first via-plugs in said first interlayer insulating film and connected with said plurality of first via-plugs,
said second wiring layer section comprises:
a second interlayer insulating film;
a plurality of second via-plugs formed in said second interlayer insulating film and separated from each other by a second distance which is longer than said first distance; and
a plurality of second wiring lines formed on said plurality of second via-plugs in said second interlayer insulating film and connected with said plurality of second via-plugs, respectively,
said plurality of first via-plugs, said plurality of first wiring lines, said plurality of second via-plugs and said plurality of second wiring lines contain metal containing copper,
said first wiring layer section has a single damascene structure, and
said second wiring layer section is a dual damascene structure.

2. The semiconductor device according to claim 1, wherein said first wiring layer section comprises a plurality of layers, each of which comprises said plurality of first via-plugs and said plurality of first wiring lines formed in said first interlayer insulating film, and
said second wiring layer section comprises a plurality of layers, each of which comprises said plurality of second via-plugs and said plurality of second wiring lines formed in said second interlayer insulating film.

3. The semiconductor device according to claim 1, wherein said first distance is set such that a via density meets a predetermined condition, said via density indicating as a number of said first via-plugs per unit area, and
said predetermined condition is that a capacitance between said first wiring lines between becomes smaller than a capacitance between said first wiring lines when said first wiring layer section is formed to have said dual damascene structure.

4. The semiconductor device according to claim 3, wherein said via density is equal to or more than 1/μm² in said predetermined condition.

5. The semiconductor device according to claim 3, were said first distance is 0.5 μm.

6. The semiconductor device according to claim 1, wherein a diameter of each of said plurality of first via-plugs is equal to or less than 0.4 μm.

7. A method of manufacturing a semiconductor device, comprising:
(a) forming a first insulating film above a semiconductor substrate;
(b) forming a plurality of first via-plugs in said first insulating film by a single damascene method, said plurality of first via-plugs being formed of metal containing copper and being separated from each other by a first distance;
(c) forming a second insulating film on said first insulating film and said plurality of first via-plugs;
(d) forming a plurality of first wiring lines in said second insulating film by a single damascene method, said plurality of first wiring lines being formed of metal containing copper and being separated from each other by said first distance;
(e) forming a third insulating film on said second insulating film and said plurality of first wiring lines; and
(f) forming a plurality of second wiring lines and a plurality of second via-plugs connected with said plurality of second wiring lines in said third insulating film by a dual damascene method, said plurality of second wiring lines and said plurality of second via-plugs being formed of metal containing copper and separated from each other by a second distance longer than said first distance.

8. The method of manufacturing the semiconductor device according to claim 7, wherein said dual damascene method is a trench-first method.

9. The method of manufacturing the semiconductor device according to claim 8, further comprising:
repeating said (a) forming step to said (d) forming step before said (e) forming step; and
repeating said (e) forming step and said (f) forming.

10. The method of manufacturing the semiconductor device according to claim 7, wherein said first distance is set such that a via density meets a predetermined condition, said via density indicating as a number of said first via-plugs per unit area, and
said predetermined condition is that a capacitance between said first wiring lines between becomes smaller than a capacitance between said first wiring lines when said first wiring layer section is formed to have said dual damascene structure.

11. The method of manufacturing the semiconductor device according to claim 10, wherein said via density is equal to or more than 1/μm² in said predetermined condition.

12. The method of manufacturing the semiconductor device according to claim 10, wherein said first distance is 0.5 μm.

13. The method of manufacturing the semiconductor device according to claim 7, wherein a diameter of each of said plurality of first via-plugs is equal to or less than 0.4 μm.
